(19) United States
(12) Patent Application Publication
(10) Pub. No.: US 2021/0164901 A1
(43) Pub. Date: Jun. 3, 2021

(54) DEVICE AND METHOD FOR DETERMINING A WAVELENGTH OF A RADIATION

(71) Applicant: UNIVERSITÄT LEIPZIG, Leipzig (DE)

(72) Inventor: Marius GRUNDMANN, Leipzig (DE)

(73) Assignee: UNIVERSITÄT LEIPZIG, Leipzig (DE)

(21) Appl. No.: 17/267,993

(22) PCT Filed: Aug. 14, 2019
(86) PCT No.: PCT/EP2019/071823

§ 371 Date: Feb. 11, 2021

(30) Foreign Application Priority Data
Aug. 14, 2018 (DE) 10 2018 119 710.1

(51) Int. Cl. G01N 21/62; H01L 31/0352; G01N 21/31

(52) U.S. Cl. CPC G01N 21/62; G01N 2021/3125; G01N 21/31; H01L 31/0352

(57) ABSTRACT

The invention relates to a device and a method for determining a wavelength of radiation.

The invention relates to a device and a method for determining a wavelength of radiation.

### PRIOR ART

Various devices and photodetectors are known in the prior art for determining a wavelength of radiation. For the detection of the wavelength of a laser, a dispersive element is usually required, which sorts the incident radiation according to wavelengths. Lattices or prisms are usually used as dispersive elements. The radiation sorted by wavelength or the radiation components can then be imaged on different locations of a photodetector array, whereby the wavelengths of the individual radiation components can be detected. A disadvantage of such a device having a dispersive element is that the device for determining the wavelength becomes very large and unwieldy as a result. In particular, if the device is to be installed in an experimental setup, it would be desirable if a space-saving and compact embodiment of such a device were available, which can nevertheless cover a comparable spectral range as the conventional devices.

In the prior art, wavelength-sensitive devices and photodetectors are known which comprise, for example, indirect semiconductors. Such indirect semiconductors usually have a slowly rising absorption spectrum. However, the disadvantage of using indirect semiconductors is that there are not corresponding semiconductor materials suitable for all wavelength ranges.

Furthermore, Fourier spectrometers are known in the prior art, using which an interferogram of the incident radiation can be created. A Fourier spectrometer usually comprises an interferometer, wherein the incident radiation is split up into individual beams within the Fourier spectrometer, which are each directed to movable or fixed mirrors and later brought together again. In this way, the interferogram can be obtained, which can then be converted into a spectrum via a Fourier transform. For example, WO 2006/071971 A2 discloses a reconfigurable, polarization-independent interferometer, wherein in the context of WO 2006/071971 A2 the incident optical signal is split, as a result of which the signal strength is undesirably lost.

In addition, monolithic solutions are known in which two photodetectors are used, which are arranged, for example, on a waveguide. For example, U.S. Pat. No. 5,760,419 A discloses a wavelength meter having two photodetectors or photodiodes between which a wavelength-dependent reflector is interposed. It is proposed that the wavelength of the incident radiation be deduced from a ratio of the photocurrents of the photodetectors. The photodetectors are identical in terms of their spectral characteristics. Selectivity for the wavelength of the incident radiation results from the wavelength-dependent reflection characteristic of the mirror. The disadvantage of this solution, however, is the expensive and complex construction of a wavelength-dependent reflector, which in the case of U.S. Pat. No. 5,760/419 A is implemented, for example, by a dielectric Bragg mirror having more than 20 layers.

In addition, the solution is associated with the disadvantage that an optical waveguide is required into which the incident radiation has to be coupled in a complex manner. This requires a high level of adjustment effort and there is a risk of measurement errors if the coupling does not succeed very precisely. Typically, waveguides having small dimensions are used, whereby the problem of alignment and focusing is exacerbated.

In addition, in the monolithic solution, the spectral range is limited to the broadening of the absorption edge of the material used. An exemplary value for such a widened absorption edge can be 16 meV, for example, wherein InGaAsP, for example, is used as the photodetector material in known monolithic solutions. The widening of the absorption edge usually results from thermal and/or statistical effects. The term “absorption edge” in terms of the invention preferably denotes a preferably sharp, i.e., abrupt transition between different absorption states or strengths. For example, this can mean a range in a preferably electromagnetic spectrum in which an abrupt difference occurs between a range of strong absorption and a range of weak absorption.

A structure for determining a wavelength of radiation is known from US 2007/0125934, which comprises a layering of a plurality of photodetectors each made of homogeneous materials, wherein the photoconductive layers are each configured for the absorption of different wavelength ranges. Using the signals from the individual detectors, conclusions can be drawn about the wavelength spectrum of the incident radiation. The layer structure of U.S. Pat. No. 6,632,701 A1 having a large number of individual detectors is, however, also complex and moreover results in a relatively large thickness. Furthermore, the working range of the device is determined by the choice of indirect semiconductors for the respective detectors, wherein the setting of the desired working ranges is severely restricted due to the material.

It is therefore the object of the present invention to provide a device and a method for determining the wavelength of radiation, which do not have the disadvantages and deficiencies of the prior art. The device is to manage without a space-consuming dispersive element and without waveguides, in order to be able to provide a compact device. Furthermore, a large wavelength range is to be able to be measured using the device and the method, wherein broadening of the absorption edge is to be in a range which clearly exceeds the values of 10 to 100 meV mentioned in the prior art. In particular, the determination of the wavelength is not to depend on thermal and/or statistical effects, but rather on the selection of materials, the design and the structure of the device or of the individual components of the device. It would also be desirable if the device could be produced using planar technology and could be illuminated from above.

### DESCRIPTION OF THE INVENTION

The object is achieved by the features of the independent claims. Advantageous embodiments of the invention are described in the dependent claims. According to the invention, a device for determining a wavelength of radiation is provided, wherein the device comprises at least two absorption elements which are arranged one above the other in a layer structure. The device is characterized in that an upper absorption element has a vertically varying chemical composition and a lower absorption element is designed to be chemically homogeneous. The device is preferably configured in a spectral detection range, wherein the upper absorption element has a vertically varying chemical composition, which is characterized by a continuous material gradient in order to set a wavelength-dependent absorption coefficient over the detection range. The lower absorption element is designed to be essentially chemically homogeneous in order to set an absorption coefficient that is essentially constant over the detection range.

The device preferably represents a wavemeter, wherein a wavemeter represents a device which is configured to establish and/or detect a wavelength and/or photon energy of radiation. A particular advantage of the invention is that the measurement of the wavelength of the incident radiation is made possible in a particularly large wavelength range, for example in the infrared (IR), visible, and/or ultraviolet (UV) spectral or wavelength range. The incident radiation can be, for example, IR or UV radiation, visible light, or laser radiation, wherein the radiation is preferably essentially monochromatic.

Terms such as essentially, about, approximately, etc. preferably describe a tolerance range of less than ±20%, preferably less than ±10%, even more preferably less than ±5%, and in particular less than ±1%. Specifications of essentially, approximately, about, etc. disclose and always comprise the exact stated value.

The term “essentially” is therefore not unclear to an average person skilled in the art, even in connection with monochromatic radiation, because a person skilled in the art knows that “essentially monochromatic radiation” preferably includes radiation having exactly one defined frequency or wavelength, wherein small deviations Δf or Δλ with regard to frequency or wavelength are to be permissible and are to be included in the term “essentially monochromatic” in the meaning of the invention. The term also preferably includes radiation in which up to 5% of the radiation deviates from the desired frequency or wavelength. In particular, there can also be a wavelength distribution, wherein, for example a peak or the maximum of a bell curve is in the range of a desired wavelength. In the context of the invention, it is particularly preferred that the radiation whose wavelength is to be determined is electromagnetic radiation. The device is preferably also referred to below as a wavemeter, wherein the invention particularly relates to a wavemeter for electromagnetic radiation.

In terms of the invention, an absorption element is a preferably layered component of a device for absorbing radiation, which can preferably be electromagnetic radiation, wherein a photosignal can be generated due to the absorption. The term absorption element for generating photosignals is preferably understood to mean absorption elements made of photoconductive materials, i.e., materials which become more electrically conductive when electromagnetic radiation is absorbed. For example, if electromagnetic radiation is absorbed by a semiconductor whose band gap is smaller than the photon energy of the electromagnetic radiation, the number of the free electrons and electron holes increases, so that the electrical conductivity increases. If an electrical voltage is applied to an absorption element, for example by means of two contacts, the possibly wavelength-dependent absorption of the electromagnetic radiation can be recorded directly as an increase in a photosignal or a photocurrent. Photosignals therefore preferably mean electrical signals which can be detected when electromagnetic radiation is absorbed by the absorption element. The photosignals are preferably photocurrents.

In the context of the present invention, an upper absorption element has a vertically varying chemical composition, which is preferably characterized by a material gradient, in order to set a wavelength-dependent absorption coefficient. A lower absorption element is designed to be chemically homogeneous in order to set an essentially constant absorption coefficient. Due to this advantageous structure, a dispersive element can be dispensed with, because the function of the dispersive element in the proposed layer structure is advantageously taken over by the upper absorption element, which has a material gradient, wherein a clear correlation of the incident wavelength with the strength of the absorption and attenuation of the radiation as it passes through the device can be provided.

For example, a first photocurrent I1 can be determined in relation to the upper absorption element and a second photocurrent I2 in relation to the lower absorption element, wherein the wavelength of the incident radiation is determinable from the signal ratio I1/I2 due to the different absorption characteristics.

For example, it can be preferred that, due to a material gradient, a wavelength-dependent absorption coefficient is set in the upper absorption element in a detection range which varies continuously over a spectral range of 100 meV, 200 meV, 500 meV, or more. Incident radiation, preferably a photosignal or photocurrent, is generated in the detection range, the quantity of which reflects the wavelength-dependent absorption coefficient in the detection range. In contrast to this, it is provided that the lower absorption element is designed to be essentially chemically homogeneous and has an essentially spectrally constant absorption coefficient over the detection range. For example, the lower absorption element can comprise a semiconductor material or a semiconductor alloy, the absorption edge of which lies below the detection range, so that a constant photocurrent is generated in the detection range of the lower absorption element, largely independently of the wavelength.

Due to the different absorption characteristics of the two absorption elements in the detection range, the wavelength of the incident radiation can be reliably concluded by means of the determination of the ratio of the photocurrents of the two absorption elements. In terms of the invention, the detection range preferably means that spectral range over which the absorption coefficient is varied as a function of the wavelength, so that the determination can be meaningfully based on the ratios of the photosignals.

According to the invention it was recognized that a wavelength-dependent absorption coefficient can be set by means of a continuous material gradient in the upper absorption element over a particularly broad detection range. Absorption coefficient is to be understood in the usual sense. As is known, the absorption of light can be described by an absorption coefficient □, which describes the attenuation of the light intensity as it passes through an absorbing medium according to Lambert-Beer's law of absorption. This means that the intensity is reduced by the factor exp (−αd) after the passage through the material of the thickness d. The unit of a is therefore 1/length; a is typically specified in cm⁻¹.

The absorption edge of a semiconductor preferably corresponds to a spectral range in which the absorption coefficient α increases from low values in the transparency range, typically less than 1 to 10 cm⁻¹, to large values, typically 10⁴ to 10⁵ cm⁻¹. In the case of compound semiconductors (e.g., GaAs, InP, GaN, ZnO) having a direct band structure, the width of this spectral range is relatively small, typically in the range of 30 meV photon energy or the corresponding wavelength range.

In a semiconductor having a direct band structure, the absorption of light is possible without the participation of lattice vibrations, which preferably results in a steep absorption edge. In semiconductors having an indirect band structure, the absorption increases more slowly, but is restricted due to the material.

There are some mechanisms that determine the exact spectral shape of a steep increase in the absorption coefficient, especially in the case of direct semiconductors, at the absorption edge. At low temperatures, so-called “excitonic” effects often contribute, at higher temperatures scattering from lattice vibrations. The typical temperatures for these effects depend on the semiconductor and its band gap. In general, however, it can be assumed that the absorption edge is broadened by thermal effects at room temperature. In mixed semiconductors or alloy semiconductors (solid state solutions, alloy semiconductors) the lattice sites of the cation or anion lattice or both lattices are occupied by different elements. Examples are (Al, Ga)As, Ga(As, P), or (Al, Ga)(As, P). Mixed semiconductors or alloy semiconductors having more than 4 elements are also possible. In this way, a constant change in the material properties between the binary end components (compound semiconductors made of two elements) can be achieved.

Such mixed semiconductors are used in many semiconductor heterostructures, that is to say structures in which multiple semiconductor layers are stacked on top of one another. Examples are light-emitting diodes, semiconductor lasers, transistors (HEMT), or multijunction solar cells.

By means of a mixed semiconductor, it is possible to specify the spectral position of the absorption edge depending on the material. The mostly random occupation of the lattice sites with multiple elements results in a slight broadening mechanism of the absorption edge, the so-called alloy broadening. Typical values for the width of the absorption edge for mixed semiconductors are 50-150 meV. The width of the absorption edge can also depend on other parameters such as electrical fields or microscopic variations in mechanical stresses in the material. For a given material, however, the width of the absorption edge is fixed.

Thus, the width of the absorption edge, i.e., the energy or wavelength range of interest for the proposed wavemeter, in which the absorption varies and preferably changes from very small values (e.g., 1 to 10 cm⁻¹) to large values (e.g., 10⁴ to 10⁵ cm⁻¹), is set for a given material.

In order to achieve a greater breadth of the absorption edge or a range having wavelength-dependent absorption coefficients and thus of the detection range of the wavemeter, it is proposed according to the invention that a chemical gradient or continuous material gradient be introduced into the upper absorption element.

The spectral position of the absorption edge preferably varies with the local chemical concentration of the constituents of a semiconductor mixture. In addition to the physical mechanisms already described, the width of the absorption edge of the overall layer (having chemical gradient) is thus determined by the superposition of the absorption edges of the various semiconductors having different chemical compositions. The shape and in particular the width of the absorption edge as well as its absolute spectral position can advantageously be determined by the suitable selection of the starting and end values of the material gradient and its functional shape (linear or non-linear, for example square). Typical achievable values are much greater than the width of the absorption edge of a single semiconductor and can be 500 meV, 1 eV, or more.

A significant advantage of the structure according to the invention is therefore that the spectral position and width of the region of the absorption edge of the upper absorption element and thus of the detection range is determined by the choice of the material gradient.

Depending on the choice of semiconductor materials, the absorption edge is in the IR, VIS, or UV. The width is determined by the course of the band gap E_{g} as a function of the concentration of the material and the breadth of the chemical variation used. For example, if x indicates the chemical variation, E_{g}(x) is the course of the band gap as a function of the chemical variation. If the chemical concentration in the layer varies from x₁ to x₂, the width of the absorption edge is therefore preferably substantially |E_{g}(x₁)−E_{g}(x₂)| plus potential dissemination mechanisms (e.g., alloy distribution, temperature-dependent scatter, inhomogeneous mechanical), which can also depend on x.

For example, the upper absorption element can comprise a semiconductor alloy in which the proportions of the alloy partners are varied vertically as a function of the layer position. Semiconductor alloy can preferably be characterized, for example, by a general form AₓB₁₋ₓ, wherein A and B are each alloy partners and x is the proportion of A in the semiconductor alloy which is varied vertically.

The use of a continuous material gradient in the upper absorption element therefore allows the provision of a wavemeter having a broad detection range (for example of 500 meV or more) whose spectral position (i.e., the starting and end points, for example 3.5 eV and 4 eV) is adjustable.

Since in the context of the present invention there is no need to provide a separate dispersive element, it is also possible to provide a particularly compact and space-saving wavemeter device which, despite the compact design, is surprisingly configured to determine wavelengths over a very large wavelength range. This represents a departure from the state of the art insofar as the technical world had previously assumed that the size of the wavemeter correlates with the wavelength range of the incident radiation to be registered later or that larger devices are required in particular to be able to detect and evaluate the wavelengths in a large spectral range.

Application tests have shown that the invention can significantly increase the influence on the absorption edge, in particular of the upper absorption element, beyond the unavoidable thermal and statistical effects. In terms of the invention, it is preferred that the absorption behavior of the upper absorption element changes with the material gradient, so that the position of absorption edges in the spectrum preferably also changes. In this respect, the present invention deliberately changes the absorption behavior of the device by providing the material gradient, wherein a change in the material gradient advantageously results in a change in the absorption behavior. In terms of the invention, it is particularly preferred that the performance parameters of the device depend only insignificantly on the thermal and/or statistical effects, but rather on the selection of materials, the design, and the structure of the device or the individual components of the device, in particular the absorption elements. It is also preferred that the device or the absorption elements can be illuminated from above.

In the context of the invention, it is very particularly preferred that the wavemeter does not comprise any waveguides, but rather that it can be produced using planar technology. In terms of the invention, the term “planar technology” is preferably to be understood such that all or a subset of the processing steps for producing the device can be carried out “from above” and/or in flat geometry. The term “processing steps” is understood to mean in particular the layer production, the structuring of photolithography masks, the etching process for structuring, the contacting of the individual elements, and/or passivations. In terms of the invention, it is particularly preferred that the components of the device, which are preferably processed on a wafer, can be processed simultaneously and in parallel. In addition, functional and/or quality tests can advantageously be carried out at the wafer level before the separation. The wafer can preferably also be used as a substrate in terms of the invention.

In the context of the present invention, the absorption edge in particular is determined by the chemical composition of the absorption elements or by the chemical gradient, in particular within the upper absorption element. The spectral sensitivity of the device or of the wavemeter advantageously depends on the semiconductor materials used and/or the alloy semiconductor materials or on the configuration of the material gradient in the upper absorber. In terms of the invention, it is preferred that the upper absorption element can also be referred to as the first absorption element and the lower absorption element as the second absorption element. The incident radiation is preferably first transmitted through the first absorption element and then the second absorption element, regardless of how the layer structure is oriented in space. It is preferred in terms of the invention that the radiation is directed onto the device in such a way that it is transmitted through the first absorption element before the second absorption element.

In terms of the invention, it can be preferred that the upper and the lower absorption element are arranged on different sides of the substrate. For example, it can be preferred that the upper absorption element is arranged on an upper side of the substrate and the lower absorption element is arranged on the other substrate side, which for example forms a lower side of the substrate. This arrangement of the layer structure is preferably referred to as an “opposite” arrangement. In the context of this embodiment of the invention, the term “layer structure” is then preferably to be understood to mean that the absorption elements can be present on different sides of the substrate or that the substrate is arranged directly or indirectly between the absorption elements. The formulation that the at least two absorption elements are arranged one above the other in a layer structure does not necessarily mean that the absorption elements are arranged on one side of the substrate, but also comprises those arrangements in which the absorption elements can be arranged on the front side and the rear side of the substrate.

The wavemeter preferably comprises a layer structure which comprises at least two absorption elements. The layer structure is preferably designed as a thin layer (thin-layer technology) and is present on a substrate which can be formed, for example, from a silicon wafer. For some applications it can also be preferred that the substrate comprises sapphire, silicon, germanium, SiC, G₂O₃, SrTiO₃, GaAs, InP, GaP, or glasses. It is particularly preferred that the substrate material is transparent in the range of the wavelength to be measured, so that the radiation to be examined can penetrate through the material. The substrate material is preferably also suitable to be used as a contact surface.

The absorption elements are arranged one above the other in the layer structure, wherein the upper absorption element is preferably also referred to as the first absorption element and the lower absorption element as the second absorption element. The absorption elements can preferably also be referred to as absorbers in terms of the invention. It is preferred in terms of the invention that the absorption elements are formed by photodetectors, wherein the photodetectors can be selected from a group comprising photoconductive detectors, pn diodes, and/or Schottky diodes, without being restricted thereto. In particular, it can also be preferred that the absorption elements comprise photosensitive layers or are formed from such layers, wherein the photosensitive layers can preferably be read out individually, i.e., can be read out individually.

The absorbers are preferably formed by semiconductors and/or semiconductor alloys having different band gaps or they comprise at least one semiconductor material; direct semiconductor materials are particularly preferred. The upper absorption element comprises a chemical gradient, which is preferably also referred to as a material gradient.

In terms of the invention, it is particularly preferred that the wavelength range to be examined is determined by the suitable selection of the materials of the absorption elements. The use of a (Mg, Zn)O alloy has proven to be particularly advantageous, for example, when UV radiation is to be examined. The upper absorber is in the form of a (Mg, Zn)O alloy or is at least partially formed from a (Mg, Zn)O material in this case.

The chemical gradient and/or the material gradient can be linear or non-linear. In the context of the present invention, the term “linear” means that the proportion of a component of the alloy or of the material from which the upper absorption element is formed has a linear, i.e., uniform and steady course from top to bottom. The proportion of a constituent or alloy partner can, for example, decrease or increase from top to bottom, wherein a plot of the proportion as a function of the thickness of the material preferably forms a straight line. The fact that the course of the chemical or material gradient extends from top to bottom is preferably referred to as a “vertical” gradient in terms of the invention. In terms of the invention, it is particularly preferred that the vertical gradient within the upper absorption element extends from materials having a high band gap to a low band gap or, conversely, from materials having a low band gap to a high band gap. For some applications it can also be preferred that the upper absorption element has a quadratic or other type of non-linear course of the material gradient. In terms of the invention, it is particularly preferred that the energetic position of the absorption edge changes over the thickness in such a way that the wavelength range is covered evenly. It is also preferred that there is in particular a linear relationship between absorption strength and wavelength and/or photon energy. These goals can be achieved, for example, in that a material composition x can be represented as a function of the thickness d as follows:

x=x₀+x₁·d+x₂·d²,

wherein the xᵢ are preferably constant coefficients. However, the dependency can also have any non-linear design. It is particularly preferred to adapt the formation of the material gradient to the dependence of the absorption edge on the concentration.

In one preferred embodiment, the material gradient is monotonically rising or falling vertically, wherein the material gradient preferably has a linear or quadratic dependence on the vertical position within the upper absorption element. The vertical position preferably denotes a coordinate position along the layer thickness of the upper absorption element.

The invention also represents a departure from the prior art insofar as the technical world has hitherto always endeavored to provide particularly homogeneous alloy systems in order to achieve the homogeneous material properties that are usually desired. In particular, the use of a continuously changing composition gradient in a semiconductor alloy turns away from the known heterostructures in which, for example, two different concentrations are used within a component in order to implement different functions of the component. This happens, for example, with so-called quantum pots, in which the “barrier” and the “pot” are implemented by different concentrations. However, the present invention turns away from precisely such components having two different material and/or element concentrations, in which in particular a continuously, preferably monotonically rising or falling, material gradient within the absorption element is proposed. For example, the material gradient within the absorption element can change linearly or essentially linearly along the vertical.

By providing the chemical gradient in the upper absorber, the spectral range in which the absorption coefficient increases from essentially zero (e.g., 1 to 10 cm⁻¹) to a high value (e.g., 10⁵ cm²) can be very large and, for example, can be in a range of a few 100 meV (for example 500 meV or 1000 meV or more). The invention thus advantageously enables the determination of wavelengths in a very large spectral range.

It is preferred in terms of the invention is that the device or the layer structure of the device is produced using methods of molecular beam epitaxy(MBE) or chemical vapor deposition(CVD) or sputtering or pulsed laser deposition (PLD). In addition, various production methods are conceivable, as long as it is possible to create a material gradient using them. The formation of a material gradient in the upper absorber can preferably be achieved by varying the partial pressures for the individual alloy components during the molecular beam epitaxy. In the case of chemical vapor deposition, the supply of a precursor can be varied, so that a desired, vertically changing composition of the first absorption element results. The chemical vapor deposition is preferably a organometallic vapor deposition. It was completely surprising that the formation of a material gradient in the upper absorption element or the precise setting of the composition of the alloy that forms the upper absorption element enables the spectral sensitivity range of the absorption edge of the wavemeter to be set and designed.

The production of a continuous vertical material gradient (gradient of the chemical composition along the growth direction) is preferably carried out in a layer deposition process via the suitable continuous regulation of the provision of various chemical elements that are to be incorporated into the layer. In the case of pulsed laser deposition, for example, this can be done via the regulation of the local position of the laser focus on the ablation target if the target is constructed in a suitable segmented manner. Various positions of the laser on the target result in ablated material having different chemical compositions (cf. Max Kneiβ, Philipp Storm, Gabriele Benndorf, Marius Grundmann, Holger von Wenckstern Combinatorial material science and strain engineering enabled by pulsed laser deposition using radially segmented targets ACS Comb. Sci. 20(11), 643-652 (2018)). By means of the method steps disclosed in Max KneiB et al., a continuous material gradient may therefore be achieved by way of example. Sufficiently small steps in the local control of the laser focus result in a continuous variation of the elements offered for the layer growth.

In the case of other typical deposition processes, other regulatory mechanisms are to be used. Further suitable methods such as molecular beam epitaxy and organometallic gas phase epitaxy for producing semiconductor layers having vertical material gradients are known from the technical literature and can be carried out by a person skilled in the art. In molecular beam epitaxy, for example, the flow of various elements from various sources can be varied by continuously adjusting the source opening and/or the source temperature. In organometallic gas phase epitaxy, various elements for layer growth can be offered by continuously regulating the introduction of various precursors into the gas flow by means of valve and flow rate control.

In terms of the invention, it is particularly preferred that the material gradient is present in a (Mg, Zn)O alloy system. A (Mg, Zn)O alloy represents a particularly preferred example of a ternary alloy for the formation of the absorption elements, wherein it is particularly preferred that the absorption elements are formed from ternary or quaternary alloys. The particularly preferred (Mg, Zn)O alloy system can preferably be formed according to the rule MgₓZn₁₋ₓO, so that more magnesium results in less zinc. The third component of the (Mg, Zn)O alloy system is oxygen.

In one preferred embodiment of the invention, the material gradient in the upper absorption element is formed by a vertical variation of the proportions of the alloy partners of a semiconductor alloy.

In a further preferred embodiment of the invention, the upper absorption element comprises a semiconductor alloy of the general form AₓB_{1-X}, wherein A and B each characterize alloy partners and x is the proportion of A in the semiconductor alloy which is varied vertically.

It can also be preferred within the meaning of the invention that the absorption elements comprise other binary, ternary, or quaternary alloys, wherein the concentrations or proportions of the individual alloy partners are coupled to one another via an index x. Depending on the selected material system of an example alloy comprising the alloy partners A and B, the index x for the alloy AₓB₁₋ₓ can preferably extend from 0 to 1 or assume a value between 0 and 1. Intermediate values such as 0 to 0.9, 0.8, 0.7, 0.6, 0.5, 0.4, 0.3, 0.2, or even 0.1 can also be preferred: it can also be preferred be to have x extend between 0.1, 0.2, 0.3, 0.4, 0.5, 0.6, 0.7, 0.8, or 0.9 to 1.0. Any combinations, for example 0.2 to 0.5 or also 0.1 to 0.3, are also conceivable. The general form AₓB₁₋ₓ is applicable to binary, ternary or quaternary alloys. For example, the alloy partners A and B can also characterize a semiconductor mixture or the upper absorption element comprises a semiconductor alloy having three or more alloy partners, wherein only the proportions of two alloy partners are varied.

For the particularly preferred embodiment MgₓZn₁₋ₓO, the presence of a chemical material gradient within the upper absorption element can preferably be expressed in such a way that the index x assumes a value between 0.3 and 0.0, varying from top to bottom, wherein the value of x=0.3 is assumed, for example, in an upper region of the absorption element and the value of x=0.0 in a lower region of the absorption element.

In the context of the invention, it can be particularly preferred that the variation of the index x over the layer thickness d can be represented in the following form:

x=x₀+x₁·d+x₂·d²,

wherein such an exemplary profile of the index x is preferably referred to as a “quadratic curve”. A linear profile, for example, as

x=x₀+x₁·d

can also be preferred.

For some applications, it can also be preferred that the course of the material gradient is described by a function

x=x₀+x₁·d+x₂·d²+x₃·d³ . . .

wherein the xᵢ preferably represents coefficients which are preferably constant. Any nonlinear functions can be set by means of such a Taylor series.

In terms of the invention, it is particularly preferred that the absorption element comprises alloy semiconductors in which a change in the chemical composition is accompanied by a change in the band gap and/or the absorption edge. Tests have shown that this requirement is met in particular by the preferred materials which are proposed in the context of the present invention. The material for the absorption elements can alternatively be selected from a group comprising (Mg, Zn)O, (In, Ga)₂O₃, (Si, Ge), (Si, Ge)C, (Al, Ga)₂O₃, (In, Ga)As, (Al, Ga)As, (In, Ga)N, (Al, Ga)N, (Cd, Zn)O, Zn(O, S), (Al, Ga, In)As, (Al, In, Ga)P, (Al, In, Ga)(As, P), (Al, Ga, ln)N, (Mg, Zn, Cd)O, and/or (Al, Ga, In)₂O₃, wherein the (In, Ga)₂O₃ and the (Al, Ga)₂O₃ are preferably arranged on sapphire.

In one preferred embodiment, the upper and lower absorption element comprises a semiconductor alloy made of direct semiconductors, particularly preferably selected from the group (Mg, Zn)O, (In, Ga)₂O₃, (Al, Ga)₂O₃, (In, Ga)As, (Al, Ga)As, (In, Ga)N, (Al, Ga)N, (Cd, Zn)O, Zn(O, S), (Al, Ga, In)As, (Al, In, Ga) P, (Al, In, Ga)(As, P), (Al, Ga, ln)N, (Mg, Zn, Cd)O, and/or (Al, Ga, In)₂O₃, wherein a person skilled in the art knows that a semiconductor alloy comprising AlGa, depending on the proportions of Al and Ga, can be a direct or indirect semiconductor, having correspondingly a direct or indirect band gap.

In contrast to the upper absorption element, the lower absorption element is designed to be chemically homogeneous. In terms of the invention, this preferably means that the constituents and/or alloy partners of the material from which the lower absorption element is formed are uniformly, i.e., preferably statistically distributed within the lower absorption element or within the layer that forms the second, lower absorption element. For example, the lower absorption element can be formed by an essentially pure ZnO layer. The term chemically homogeneous in relation to the lower absorption element therefore preferably means a material composition which is essentially not varied vertically, but is essentially uniform or statistically constant along the vertical.

The lower absorption element is preferably set up to absorb all wavelengths in the wavelength range of the incident radiation, so that the wavelengths of the incident radiation can be determined using the wavemeter. In terms of the invention, it is preferred that the lower absorber is designed to be sensitive to a broad range of wavelengths in the sensitivity range. The first and the second absorption element can be formed from the same material. However, in terms of the invention it can also be preferred that the absorption elements consist of different materials.

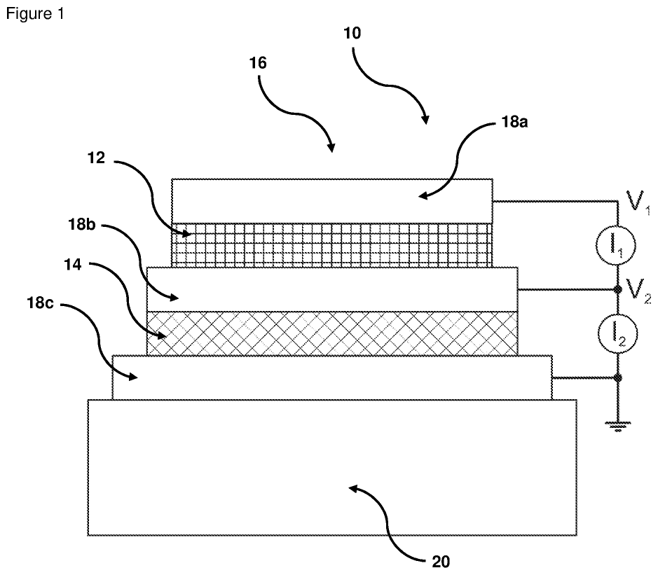

In terms of the invention, it is preferred that a first photocurrent I1 is ascertainable with respect to the upper absorption element and a second photocurrent I2 is ascertainable with respect to the lower absorption element, wherein the wavelength of the incident radiation is determinable from the signal ratio I1/I2. In terms of the invention, it is preferred that the layer structure between the absorption elements comprises contacts, wherein the photocurrents I1 and I2 are measurable between the contacts. It is particularly preferred that the photocurrent I1 can be measured between the contacts that surround the upper absorption element, while the photocurrent I2 can be measured between the contacts that surround the lower absorption element. If the device consists of two absorption elements, the wavemeter preferably has three contacts, wherein the contacts from top to bottom are preferably referred to as first, second, and third contacts. In terms of the invention, it is preferred that the upper absorption element is arranged between the first and the second contact and that the photocurrent I1 is measured between the first and the second contact. It is further preferred that the lower absorption element is arranged between the second and the third contact and that the photocurrent I2 is measured between the second and the third contact. This is also shown in FIG. 1, for example. In terms of the invention, it is preferred that the photocurrent is a current that flows, due to the irradiation of the absorption elements, between the contacts that surround the absorption elements and to which a voltage is preferably applied. In terms of the invention, it is particularly preferred that the absorption of the radiation releases charge carriers in the absorption elements. Depending on the amount and/or energy of the absorbed radiation, different numbers of charge carriers are released, wherein the charge carriers can in particular also have different particle energies. These particle energies are preferably specified in units of electron volts (eV). A photocurrent is preferably formed from the released charge carriers. In terms of the invention, it is preferred that the wavelength of the radiation to be examined can be reconstructed from the ratio of the photocurrents I1 and I2.

In one preferred embodiment, the device comprises a data processing device, which is configured to calculate the ratio of the signals of the photocurrents and to determine the wavelength of the radiation in consideration of the ratio.

The data processing device is preferably a unit which is suitable and configured for receiving, transmitting, storing, and/or processing data, preferably photocurrents or other measurement data. The data processing unit preferably comprises an integrated circuit, a processor, a processor chip, a microprocessor, and/or microcontroller for processing data, as well as a data memory, for example a hard disk, a random access memory (RAM), a read-only memory (ROM), or also a flash memory for storing the data.

To carry out the calculation of the ratio of the signals of the photocurrents and determination of the wavelength of the radiation taking into consideration the ratio, software, firmware, or a computer program can preferably be stored on the data processing device, which comprises commands to carry out the steps disclosed in conjunction with the method.

The data processing device can, for example, be a microprocessor which is installable compactly in a housing with the device. However, a personal computer, a laptop, a tablet, or the like is also conceivable which, in addition to means for receiving, transmitting, storing, and/or processing data, also comprises a display of the data and an input means, for example a keyboard, a mouse, a touchscreen, etc. A person skilled in the art recognizes that preferred (calculation) steps which are disclosed in conjunction with the method can also preferably be carried out by the data processing device. For example, calibration data can preferably be present on the data processing device which are used to determine the wavelength from the ratio of the photocurrents.

In terms of the invention, it can furthermore be preferred to arrange the absorption elements on the front side and/or the rear side of a substrate, wherein the substrate is preferably formed by a wafer. For example, it may be preferred to apply the first or upper absorption element to a front side of the substrate and the second or lower absorption element to a rear side of the substrate. In terms of the invention, it can also be preferred to proceed in reverse. In the context of the invention, it can be particularly preferred to process the two substrate halves, for example, independently of one another and/or one after the other. The photodetectors obtained in this way can preferably be referred to as “opposite photodetectors” in terms of the invention. For the production of these opposite photodetectors, it is preferred that the substrate is at least partially transparent to the radiation in the wavelength range of interest. This advantageously avoids intermediate contacts at which photosignals can be lost, which can result in attenuation of the signal to be detected. In terms of the invention, it is preferred that the photodetectors are each designed identically or differently as photoconductive, pn, and/or Schottky diodes. In this embodiment of the invention it is particularly preferred that the first and the second absorption element are each attached to one side of the substrate.

It is preferred in terms of the invention that the device comprises a number N absorption elements and a number of at least N+1 contacts. It can also be preferred in terms of the invention that the wavemeter comprises more than two absorption elements. In this embodiment of the invention, it is particularly preferred that the different absorption elements absorb radiation in different wavelength ranges. In other words, the various absorption elements can be configured to absorb radiation in different wavelength ranges or to detect and/or determine the corresponding different wavelengths. This is associated with the advantage that a spectral intensity distribution can thus be measured separately in this range. The contacts can preferably also be designed as contact regions or contact layers. The absorption elements can preferably also be formed in layers, so that the absorption elements are arranged, for example, between the contact layers and can form a sandwich-like layer structure. For example, a proposed device can comprise a layer structure having multiple absorption elements, each of which has a material gradient. Such a layer structure is preferably referred to in terms of the invention as a layer structure having multiple gradient layers as absorption elements. Such a layer structure can comprise one or more homogeneous layers as absorption elements in addition to the gradient layers. These homogeneous layers can be arranged between the gradient layers or as a starting and/or end layer of a preferred layer structure. In terms of the invention, it is particularly preferred if the homogeneous layers are adapted to the gradients of the gradient layers in terms of design and material.

In terms of the invention, it is preferred that N photocurrents can be ascertained if the layer structure comprises N absorption elements. In terms of the invention, it is very particularly preferred that the radiation to be examined is transmitted through the individual absorption elements one after the other, wherein the absorption elements having a higher-energy absorption edge are passed through first. In other words, it is preferred in terms of the invention that the incident radiation is guided through the absorption elements one after the other, wherein the absorption elements are arranged with regard to the incident radiation in such a way that the absorption elements having a higher-energy absorption edge are first crossed and other absorption elements having a lower absorption edge will have the incident radiation transmitted through them later. In terms of the invention, it is very particularly preferred that the absorption elements are arranged in the layer structure according to their absorption edge, wherein the absorption elements having a higher-energy absorption edge are preferably arranged in the region of the layer structure on which the incident radiation initially strikes.

In terms of the invention, it is preferred that the contacts are designed to be electrically conductive and transparent to radiation in a defined wavelength range. A person skilled in the art can select suitable materials. The conductivity of the contacts can be achieved, for example, in that the contacts are produced from a conductive material or that the contacts have a conductive coating on their surface. For example, the contacts can be formed from a (Mg, Zn)O alloy, which can be doped with aluminum (Al) or gallium (Ga), for example. In terms of the invention, it can also be preferred that the contacts comprise electrically conductive layers. The term “in a defined wavelength range” can preferably be understood as a specific, selected, and/or special wavelength range. In the context of the present invention, this is intended to mean the wavelength range of the incident radiation, which is preferably also referred to as the “relevant wavelength range”. Transparency in a defined wavelength range thus preferably means in terms of the present invention that the transparent components of the device do not or only insignificantly absorb radiation in the wavelength range of the incident radiation. In terms of the invention, it is preferred that the term “relevant wavelength range” denotes the wavelength range in which it is possible to clearly determine the wavelength of the incident radiation.

It is preferred in terms of the invention that the absorption elements are configured to absorb radiation in the defined wavelength range. This also applies in particular to the lower absorption element. In terms of the invention, this preferably means that the second absorber absorbs all wavelengths in the relevant wavelength range. This is also achieved in particular by a sufficiently large thickness d2 of the material layer which, for example, forms the lower absorber. In terms of the invention, it is preferred that the thickness of the absorption elements can be selected as a function of the absorption capacity of the material. A thickness of the absorption elements is preferably in the range of the inverse absorption coefficient of the corresponding material. The thicknesses of the absorption elements can, for example, be in a range from 100 to 200 nm, preferably between 140 and 160 nm, and most preferably 150 nm. In terms of the invention, it can be preferred that the thicknesses d1 and d2 are equal; however, it can also be preferred for other applications that the thicknesses d1 and d2 have different values. In the case of indirect semiconductors, greater thicknesses of, for example, 100 μm can also be preferred.

In the context of the present invention, a first photocurrent I1 can be ascertained in relation to the upper absorption element and a second photocurrent I2 can be ascertained in relation to the lower absorption element. It is preferred in terms of the invention that the photocurrents are preferably also referred to as photosignals, so that in terms of the invention it can be particularly preferred to ascertain photosignals in relation to the absorption elements of the device, wherein a wavelength of the incident radiation can be determined from the signal ratio of the photosignals of the two absorption elements. The photocurrents for an absorption element are each measured between the contacts between which the respective absorption element is arranged, wherein, for example a voltage V1 is applied to the first contact of the wavemeter and a voltage V2 is applied to the second contact of the wavemeter. The wavelength of the incident radiation can then be determined from the signal ratio I1/I2, wherein the signal ratio I1/I2 is preferably also referred to as the quotient of the photocurrents. In terms of the invention, it is preferred that the signal ratio depends on the wavelength of the incident radiation, wherein the signal ratio in particular is dependent on the wavelength of the incident radiation in a mathematically strictly monotonic manner. In terms of the invention, it is preferred that the layer structure, comprising contacts and absorption elements or comprising contact layers and photoresistive layers which form the absorption elements, is arranged on a substrate.

In a further aspect, the invention relates to a method for determining a wavelength of radiation, which comprises the following steps:
a) Providing a device for detecting a wavelength of radiation,
b) providing radiation whose wavelength is to be determined, wherein the radiation is directed onto the device,
c) absorbing a first component of the radiation by way of the upper absorption element and converting it into a photocurrent signal I1,
d) absorbing a second component of the radiation by way of the lower absorption element and converting it into a photocurrent signal I2
e) determining the wavelength of the radiation in consideration of the signal ratio I1/I2.

It is preferred in terms of the invention that the device with which the method is carried out is a device proposed here for determining a wavelength of radiation. The definitions, technical effects, and surprising advantages described for the device apply analogously to the proposed method. In particular, the device is to be a wavemeter which comprises at least two absorption elements, wherein the absorption elements are arranged one above the other in a layer structure. Furthermore, it is preferred that an upper absorption element has a vertically varying chemical composition, which is characterized by a continuous material gradient which sets a wavelength-dependent absorption coefficient over the detection range. A lower absorption element is designed to be chemically homogeneous. In the context of the invention, it is preferred that the absorption elements are arranged directly one above the other on the substrate and/or a carrier material. For other applications it can also be preferred that the absorption elements are present separated from one another by a transparent substrate, for example on the front side and the rear side of the substrate, which can be formed, for example, by a wafer. In terms of the invention, it can be preferred that the upper and the lower absorption element are arranged on different sides of the substrate. For example, it can be preferred that the upper absorption element is arranged on an upper side of the substrate and the lower absorption element is arranged on the other substrate side, which for example forms a lower side of the substrate. This arrangement of the layer structure is preferably referred to as an “opposite” arrangement.

In terms of the invention, it is preferred that the signal ratio depends on the wavelength of the incident radiation, wherein the signal ratio in particular is dependent on the wavelength of the incident radiation in a mathematically strictly monotonic manner.

It is furthermore preferred that the device can be illuminated from above while the method is being carried out. In terms of the invention, this preferably means that the radiation preferably first falls on the upper absorption element and then penetrates through the further layers of the layer structure. The fact that the device is illuminated from above when the method is carried out can preferably be achieved by providing the radiation, the wavelength of which is to be determined, wherein the radiation is preferably directed onto the device—for example from above.

The upper absorption element, which preferably has a chemically vertically varying material gradient, is preferably configured to absorb a first component of the incident radiation and to convert it into a photocurrent signal I1. The upper absorber can have the necessary means for this purpose. In this context, the proposed method comprises the absorption of a first component of the radiation by the upper absorption element and the conversion of the radiation into a photocurrent signal I1. The lower absorption element is preferably configured to absorb a second component of the incident radiation and convert it into a photocurrent signal I2, wherein the second absorber preferably is preferably designed to be homogeneous chemically and in terms of composition. The lower absorber can also have the corresponding required means for converting the radiation into a photocurrent signal. In this context, the proposed method comprises the absorption of a second component of the radiation by the lower absorption element and the conversion of the radiation into a photocurrent signal I2. In other words, it is preferred that the upper absorption element has a vertically varying chemical composition and the lower absorption element is designed to be chemically homogeneous, wherein a first photocurrent I1 is ascertainable with respect to the upper absorption element and a second photocurrent I2 is ascertainable with respect to the lower absorption element.

In a further process step, the wavelength of the radiation is determined taking into consideration the signal ratio I1/I2. In particular, the wavelength of the radiation incident from above on the device or the wavemeter is determined. In terms of the invention, it is preferred that the wavelength of the incident radiation can be determined from the signal ratio I1/I2. This can advantageously be achieved in that there is a preferably strictly monotonic dependence between the wavelength and the photocurrent quotient I1/I2, so that the wavelength can advantageously be inferred from the ratio between the variables.

For the purposes of the invention, it is preferred that the device can be calibrated by measuring the photocurrent ratio using monochromatic light sources of known wavelength. Thus, the invention is preferably designed to be calibratable in terms of the invention.

The invention will be described in greater detail on the basis of the following figures; in the figures:

FIG. 1 shows a representation of a schematic cross section through a preferred embodiment of the invention

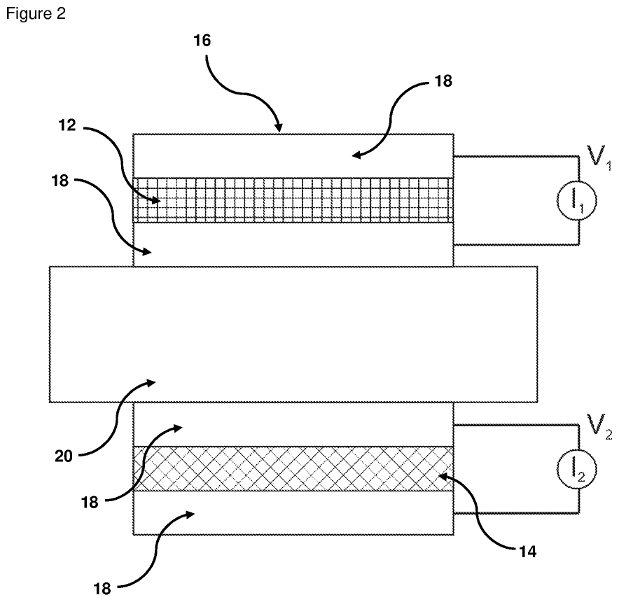

FIG. 2 shows a representation of an alternative embodiment of the invention

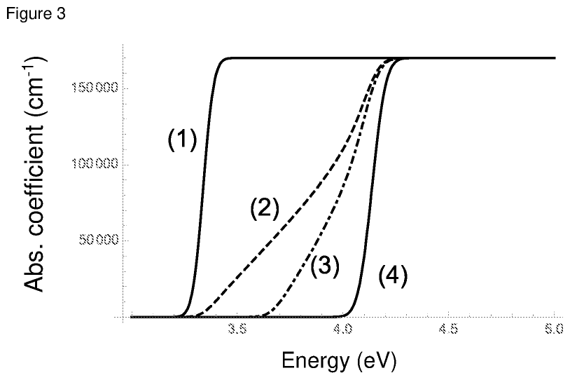

FIG. 3 shows an illustration of an exemplary design of the absorption spectrum by means of a variation in the proportions of the alloy partners of a semiconductor alloy

FIG. 1 shows a schematic cross section through a preferred embodiment of the invention (10) and in particular a side view of a preferred embodiment of the proposed device (10). A layer structure (16) is shown which comprises absorption elements (12, 14) and contacts (18a, 18b, 18c). The layer structure (16) shown in FIG. 1 terminates at the top with an upper or first contact (18a). A photoresistive layer, which preferably forms the upper absorption element (12), is arranged below the first contact (18a). The second or middle contact (18b) is arranged below the upper absorber (12). It is preferred in terms of the invention that a photon current I1 can be measured between the first contact (18a) and the second contact (18b), which is brought into connection with the upper absorption element (12), wherein a voltage V1 can be applied to the first contact (18a) and a voltage V2 can be applied to the second contact (18b). The lower absorption element (14) is arranged below the second contact (18b). The third or lower contact (18c) is arranged below the lower absorber (14), wherein the five layers mentioned (12, 14, 18a, 18b, and 18c) form the layer structure (16) of the wavemeter (10), wherein the layer structure (16) can preferably be arranged on a substrate (20).

FIG. 2 shows an alternative embodiment of the invention. In particular, FIG. 2 shows a layer structure (16) in which the absorption elements (12, 14) are arranged on different sides of a substrate (20). In the exemplary structure shown in FIG. 2, the upper absorption element (12) is arranged on an upper side of the substrate (20), while the lower absorption element (14) is arranged on a lower side of the substrate (20). Contacts (18a, b, c) or contact layers can preferably be arranged between each of the absorption elements (12, 14) and the substrate (20). The entirety of the contact layers 18a, b, c is preferably described in the description of the figures and the claims by the reference symbol “18”. In terms of this embodiment of the invention, it is preferred that the photosignals, in particular the photocurrents, are measured between two contacts (18) which each surround the first absorption element (12) and the second absorption element (14). According to the invention, it is very particularly preferred that the first photosignal, which is preferably formed by a first photocurrent I1, is measured between the two contacts (18) which surround the first absorption element (12). According to the invention, it is also preferred that the second photosignal, which is preferably formed by a second photocurrent I2, is measured between the two contacts (18) which surround the second absorption element (14). The photosignal is preferably induced in each case in that charge carriers are released by the incident radiation in the absorption element (12, 14), wherein the charge carriers move within the absorption element (12, 14) due to the applied voltage in an oriented movement from one contact (18) to the other contact (18). This charge carrier current can preferably be measured as a photocurrent.

FIG. 3 illustrates, by way of example, a design or the setting option of an absorption spectrum by means of a variation of the proportions of the alloy partners of a semiconductor alloy.

By way of example, the mode of operation will be described using the example of a (Mg, Zn)O system, wherein the principles explained can be applied analogously to other semiconductor alloy systems. In the (Mg, Zn)O mixed semiconductor having the chemical formula MgₓZn₁₋ₓO, x indicates the Mg content.

In FIG. 3, the schematic absorption spectra for x=0 (i.e., pure ZnO) and x=0.4 (i.e., Mg_{0.4}Zn_{0.6}O) are shown as solid lines (1) and (4), respectively. The absorption edge for x=0 extends approximately in the spectral range of 3.25-3.45 eV. The absorption edge for x=0.4 extends approximately in the spectral range of 4.0-4.2 eV. If the chemical concentration is varied continuously and linearly in a layer from x=0 to x=0.4 during growth (vertical material gradient), the result is the absorption spectrum (2) shown by dashed lines. Here the absorption increases continuously over the entire broad spectral range from approximately 3.3-4.2 eV between the absorption edges of ZnO and Mg_{0.4}Zn_{0.6}O. If the chemical concentration is varied continuously and linearly in a layer from x=0.2 to x=0.4, the result is the absorption spectrum (3) shown by dot-dash lines. Here the width of the spectral range of the absorption edge is now smaller, approximately 3.6-4.2 eV.

By means of variation of the alloy partners of the semiconductor system to set the material gradient, a wavelength-dependent absorption coefficient can thus be set for a preferred detection range. In the case of an upper absorption element having an absorption spectrum (2), the detection range would extend, for example, from 3.3 eV to 4.2 eV and therefore over a spectral range of almost 1 eV. The lower absorption element will preferably have an absorption coefficient that is essentially wavelength-independent over the detection range. In relation to the example, Mg_{0.0}Zn_{1.0}O, i.e. pure ZnO, would be suitable, which from 3.3. eV has a high absorption coefficient. Alternatively, in particular other semiconductors or semiconductor alloys would also be conceivable, whose absorption edge is preferably below 3.3 eV.

### LIST OF REFERENCE SIGNS

10 device, in particular wavemeter
12 upper absorption element
14 lower absorption element
16 layer structure
18 contacts (a: first contact, b: second contact, c: third contact)
20 substrate

1. A device (10) for determining a wavelength of radiation comprising at least two absorption elements (12, 14) for generating photosignals, wherein the absorption elements (12, 14) are arranged in a layer structure (16) one above the other,
characterized in that
an upper absorption element (12) has a vertically varying chemical composition, which is characterized by a material gradient in order to set a wavelength-dependent absorption coefficient, and a lower absorption element (14) is designed to be chemically homogeneous.

2. The device (10) according to claim 1,
characterized in that
the absorption elements (12, 14) comprise at least one semiconductor material.

3. The device (10) according to claim 1 or 2,
characterized in that
the absorption elements (12, 14) comprise binary, ternary, or quaternary alloys of semiconductors, preferably direct semiconductors.

4. The device (10) according to any one or more of the preceding claims,
characterized in that
the material gradient is varied monotonically rising or falling vertically, wherein the material gradient preferably has a linear or quadratic dependence on the vertical position within the upper absorption element (12).

5. The device (10) according to any one or more of the preceding claims,
characterized in that
the material gradient in the upper absorption element (12) is formed by a vertical variation of the proportions of the alloy partners of a semiconductor alloy.

6. The device (10) according to any one or more of the preceding claims,
characterized in that
the upper absorption element (12) comprises a semiconductor alloy of the general form AₓB_{1-X}, wherein A and B each characterize alloy partners and x is the proportion of A in the semiconductor alloy which is vertically varied.

7. The device (10) according to any one or more of the preceding claims,
characterized in that
the upper absorbent element has a monotonically rising or monotonically falling absorption coefficient over a spectral range of at least 100 meV, preferably at least 200 meV, more preferably at least 300 meV.

8. The device (10) according to any one or more of the preceding claims,
characterized in that
a material for the absorption elements (12, 14) is selected from a group comprising (Mg, Zn)O, (In, Ga)₂O₃, (Si, Ge), (Si, Ge)C, (Al, Ga)₂O₃, (In, Ga)As, (Al, Ga)As, (In, Ga)N, (Al, Ga)N, (Cd, Zn)O, Zn(O, S), (Al, Ga, In)As, (In, Ga)(As, P), (Al, Ga, In)N, (Mg, Zn, Cd)O, or (Al, Ga, In)₂O₃.

9. The device (10) according to any one or more of the preceding claims,
characterized in that
the absorption elements (12, 14) are configured to absorb radiation in a defined wavelength range.

10. The device (10) according to any one or more of the preceding claims,
characterized in that
the layer structure (16) comprises a substrate (20), wherein the upper absorbent element (12) and the lower absorbent element (14) are arranged on different sides of the substrate (20).

11. The device (10) according to the preceding claim,
characterized in that
the substrate (20) is at least partially transparent to the radiation.

12. The device (10) according to any one or more of the preceding claims,
characterized in that
the layer structure (16) comprises contacts (18) between the absorption elements (12, 14), wherein photosignals in the form of photocurrents are measurable between the contacts (18).

13. The device according to any one or more of the preceding claims,
characterized in that
the device comprises a data processing device which is configured to calculate the ratio of the signals of the photocurrents and to determine the wavelength of the radiation in consideration of the ratio.

14. A method for determining a wavelength of radiation
comprising the following steps
a) providing a device for detecting a wavelength of radiation according to any one of the preceding claims,
b) providing radiation, the wavelength of which is to be determined, wherein the radiation is directed onto the device,
c) absorbing a first component of the radiation by way of an upper absorption element (12) and converting it into a photocurrent signal I1,
d) absorbing a second component of the radiation by way of a lower absorption element (14) and converting it into a photocurrent signal I2,
e) determining the wavelength of the radiation taking into consideration the signal ratio I1/I2.

15. The method according to the preceding claim, characterized in that
the signal ratio is dependent on the wavelength of the incident radiation.
